(19) United States
(12) Patent Application Publication
(10) Pub. No.: US 2026/0314327 A1
(43) Pub. Date: Oct. 8, 2026

(54) AUXILIARY RING IN SUBSTRATE PROCESSING APPARATUS

(71) Applicant: Samsung Electronics Co., Ltd., Suwon-si (KR)

(72) Inventors: Sangjine PARK, Suwon-si (KR); Ji Hwan PARK, Suwon-si (KR)

(73) Assignee: Samsung Electronics Co., Ltd., Suwon-si (KR)

(21) Appl. No.: 19/573,826

(22) Filed: Mar. 20, 2026

(30) Foreign Application Priority Data
Apr. 3, 2025 (KR) 10-2025-0043355

(51) Int. Cl. H10P 72/76; H01J 37/32; H10P 72/00

(52) U.S. Cl. CPC H10P 72/7611; H10P 72/0421; H01J 37/32623; H01J 2237/334

(57) ABSTRACT

A substrate processing apparatus includes a chamber defining a processing space, a stage in the processing space and having an upper surface on which a substrate is loaded, an auxiliary ring extending along an edge of the upper surface of the stage, and an actuator configured to adjust an exposed area of the auxiliary ring in a plan view. The substrate may include an etch target, and the auxiliary ring may include the same material as the etch target of the substrate.

### CROSS-REFERENCE TO RELATED APPLICATION(S)

This U.S. non-provisional application claims priority under 35 USC § 119 to Korean Patent Application No. 10-2025-0043355, filed on Apr. 3, 2025, in the Korean Intellectual Property Office, the disclosure of which is herein incorporated by reference in its entirety.

### BACKGROUND

The present disclosure relates to a substrate processing apparatus and, more particularly, to a substrate processing apparatus for performing an etching process on a substrate.

Semiconductor devices may be manufactured through various manufacturing processes. In an etching process, etchants may attack a substrate to remove certain materials physically and chemically. To improve the productivity of semiconductor devices, etchants should uniformly etch the substrate, in the plan view, during the etching process. Etching apparatuses employing various technologies are being researched and developed to increase the reliability of etching processes in the mass production of semiconductor devices.

### SUMMARY

The present disclosure provides a substrate processing apparatus having enhanced reliability of an etching process.

The present disclosure provides a substrate processing apparatus configured to etch a substrate uniformly in a plan view.

The present disclosure provides a substrate processing apparatus configured to control an etching reaction rate in an etching process.

The present disclosure provides a substrate processing apparatus configured to control the amount of products generated by an etching reaction in an etching process.

According to at least one embodiment, a substrate processing apparatus includes a chamber defining a processing space, a stage in the processing space and having an upper surface on which a substrate is loaded, an auxiliary ring extending along an edge of the upper surface of the stage, and an actuator configured to adjust a size of an exposed area of the auxiliary ring in a plan view. The substrate may include an etch target, and the auxiliary ring may include the same material as the etch target of the substrate.

According to at least one embodiment, a substrate processing apparatus includes a chamber defining a processing space, a stage in the processing space configured to support a substrate, a plurality of auxiliary blades arranged along an edge of the stage, and an actuator coupled to the plurality of auxiliary blades. The substrate may include an etch target, each of the plurality of auxiliary blades may include the same material as the etch target of the substrate, and the actuator may be configured to adjust a shortest distance between each of the plurality of auxiliary blades and the stage.

According to at least one embodiment, a substrate processing apparatus includes a chamber defining a processing space, a stage in the processing space, the stage comprising an upper surface on which a substrate is loaded and a seating portion recessed along an edge of the stage, an auxiliary ring on the seating portion of the stage, a plurality of cover blades arranged along the edge of the stage, and an actuator configured to drive the plurality of cover blades to adjust a size of an exposed area of the auxiliary ring in a plan view. The plurality of cover blades may be configured to extend from the actuator to cover the auxiliary ring and to be inserted into the actuator to expose the auxiliary ring, the substrate may include an etch target, and the auxiliary ring may include the same material the etch target of the substrate.

### BRIEF DESCRIPTION OF DRAWINGS

FIG. 1 is a schematic cross-sectional view illustrating a substrate processing apparatus according to one or more embodiments.

FIG. 2 is a graph illustrating the concentration of a portion of etching products based on a horizontal location of a substrate according to one or more embodiments.

FIG. 3 is an exploded perspective view of a portion of the substrate processing apparatus according to one or more embodiments.

FIG. 4 is a plan view of a fixing ring according to one or more embodiments.

FIG. 5 is a plan view of a drive ring according to one or more embodiments.

FIG. 6 is a perspective view of an auxiliary blade according to one or more embodiments.

FIG. 7 is a flowchart illustrating a method of operating the substrate processing apparatus according to one or more embodiments.

FIG. 8 is a plan view illustrating the operation of an auxiliary blade according to one or more embodiments.

FIG. 9 is a plan view illustrating the operational state of auxiliary blades according to one or more embodiments.

FIG. 10 is a plan view illustrating the operating state of auxiliary blades according to one or more embodiments.

FIG. 11 is an exploded perspective view of a portion of the substrate processing apparatus according to one or more embodiments.

FIG. 12 is a partial cross-sectional perspective view of the substrate processing apparatus according to one or more embodiments.

FIG. 13 is a perspective view of a cover blade according to one or more embodiments.

FIG. 14 is a perspective view of a cover blade according to one or more embodiments.

FIG. 15 is a plan view illustrating operating states of cover blades according to one or more embodiments.

FIG. 16 is a plan view illustrating an operating state of a single cover blade among cover blades according to one or more embodiments.

FIG. 17 is a plan view illustrating operating states of cover blades according to one or more embodiments.

FIG. 18 is a plan view illustrating an operating state of a single cover blade among cover blades according to one or more embodiments.

FIG. 19 is a plan view illustrating operating states of cover blades according to one or more embodiments.

FIG. 20 is a plan view illustrating an operating state of a single cover blade among cover blades according to one or more embodiments.

### DETAILED DESCRIPTION

The following description with reference to the accompanying drawings is provided to assist in a comprehensive understanding of various embodiments of the present disclosure.

Although the terms “first,” “second,” “third,” etc., may be used herein to describe various elements, components, regions, layers, and/or sections, these elements, components, regions, layers, and/or sections, should not be otherwise limited by these terms. These terms are only used to distinguish one element, component, region, layer, or section, from another region, layer, or section. Thus, a first element, component, region, layer, or section, discussed below may be termed a second element, component, region, layer, or section, without departing from the scope of this disclosure.

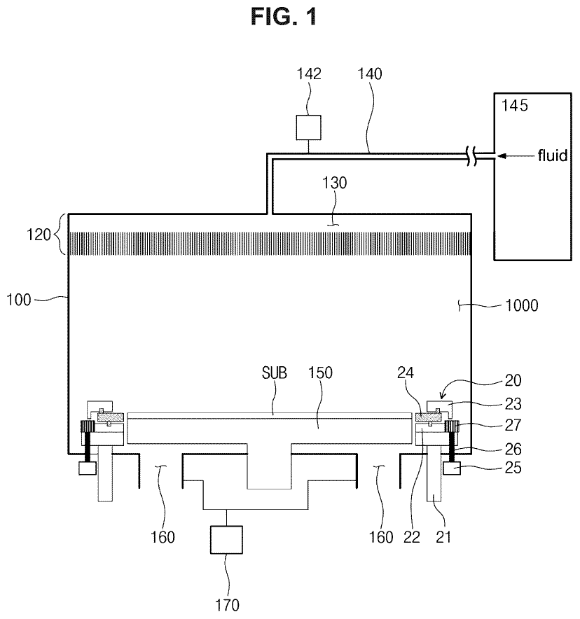

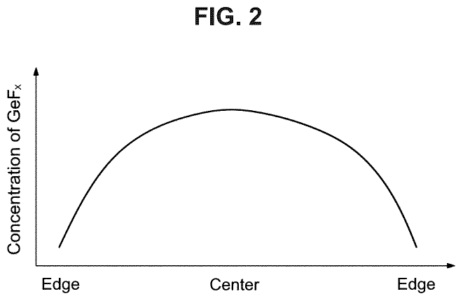

FIG. 1 is a schematic cross-sectional view illustrating a substrate processing apparatus 1 according to one or more embodiments. FIG. 2 is a graph illustrating the concentration of a portion of etching products based on a horizontal location of a substrate according to one or more embodiments.

Referring to FIG. 1, in one or more embodiments, the substrate processing apparatus includes a chamber 100 having a processing space 1000, a stage 150 within the processing space 1000, an auxiliary ring 24 at the edge of the stage 150, and an actuator 20 controlling the auxiliary ring 24. The auxiliary ring 24 may be provided between a fixing ring 23 and a drive ring 22. For example, the auxiliary ring 24 may be provided between the fixing ring 23 and the drive ring 22. For example,

The substrate processing apparatus 1 is configured to perform a semiconductor manufacturing process on a substrate SUB. For example, the substrate processing apparatus 1 may be an etching apparatus performing an etching process on the substrate SUB.

The chamber 100 may have (or define) a processing space 1000. The processing space 1000 may refer to an internal space of the chamber 100, in which the substrate SUB is processed. The processing space 1000 may also be referred to as a process space.

The chamber 100 may include a supply pipe 140 configured to allow a process fluid to flow into the processing space 1000. The process fluid may be supplied into the chamber 100 through the supply pipe 140 from a supply source 145. The supply pipe 140 may be connected to a ceiling of the chamber 100. For example, in at least one embodiment, the process fluid may be (and/or include) an etching gas; and the etching gas may be introduced into the chamber 100 through the supply pipe 140 connected to the ceiling of the chamber 100, and plasma may be generated in the processing space (e.g., when high-frequency power is applied to the chamber).

The chamber 100 may further include a flow meter 142 connected to the supply pipe 140. The flow meter 142 may measure and/or control a flow rate of the process fluid passing through the supply pipe 140.

The chamber 100 may include a shower head 120 configured to distribute the process fluid. The shower head 120 may include a buffer space 130 into which the process fluid is introduced and a plurality of shower head holes, not labeled, configured to allow the process fluid to pass therethrough. The shower head holes may connect the processing space 1000 and the buffer space 130. For example, the etching gas may be introduced into the buffer space 130 through the supply pipe 140, and the etching gas in the buffer space 130 may be uniformly distributed into the processing space 1000 through the shower head holes.

The chamber 100 may further include an exhaust port 160 through which the process fluid is discharged. In at least one embodiment, the exhaust port 160 may be disposed below the stage 150. For example, the exhaust port 160 may be provided on a bottom surface of the chamber 100. In addition, the chamber 100 may be configured such that products, byproducts, waste gases, and fumes generated during the etching process may be discharged from the chamber 100 through the exhaust port 160.

The chamber 100 may further include an exhaust pump 170 connected to the exhaust port 160. The exhaust pump 170 may control a flow rate of the process fluid discharged through the exhaust port 160. For example, the exhaust pump 170 may adjust a pressure in the exhaust port 160 to control the flow rate and/or discharge rate of the process gas discharged from the processing space 1000 to the exhaust port 160.

The stage 150 may be configured to support the substrate SUB. The stage 150 may include an upper surface 152 on which the substrate SUB is loaded. The stage 150 may include an electrostatic chuck ESC configured to fix and support the substrate SUB using electrostatic force. The stage 150 may be provided within the chamber 100. The stage 150 may be located in the processing space 1000. For example, the substrate SUB may be loaded onto the stage 150, and a semiconductor manufacturing process may be performed on the substrate SUB on the stage 150.

The stage 150 may be configured to control a temperature. For example, the stage 150 may include a temperature regulator, not illustrated, configured to heat and/or cool the upper surface 152. In one or more embodiments, the temperature regulator may be (or include) a heater and/or may also cool the upper surface 152 of the stage 150. For example, the stage 150 may heat or cool the loaded substrate SUB to a temperature suitable for the manufacturing process using a heater provided therein. In at least one example embodiment, the temperature regulator may be a thermoelectric element.

The substrate SUB may include a semiconductor substrate. The substrate SUB may include etch targets, not illustrated. The etch targets may be provided on a front surface of the substrate SUB. The etch targets may include semiconductor materials. For example, the etch targets may include at least one of silicon, germanium, or carbon.

For example, the etch targets may be a stack structure in which semiconductor layers and sacrificial semiconductor layers are alternately stacked using an epitaxial growth process. The semiconductor layers may include a material having etch selectivity compared to a material of the sacrificial semiconductor layers. In one or more embodiments, the semiconductor layers may include silicon, and the sacrificial semiconductor layers may include silicon-germanium.

For example, process fluid may be supplied to the processing space 1000 through the supply pipe 140. The process fluid may selectively etch the sacrificial semiconductor layers of the etch targets. The process fluid may etch the silicon-germanium included in the sacrificial semiconductor layers. According to at least one embodiment process fluid may include an etching gas including fluoride (F). For example, in at least one embodiment, the etching gas may include HF. An etching reaction of silicon-germanium by the process fluid, according to the at least one embodiment, may be represented as illustrated in the following Chemical Formula 1.

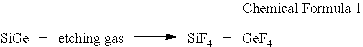

The product GeF₄ generated through Chemical Formula 1 may react again with silicon and germanium. The reaction between GeF₄ and silicon and the reaction between GeF₄ and germanium may be represented as illustrated in the following Chemical Formula 2.

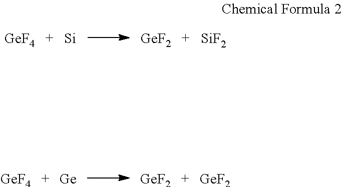

According to Chemical Formula 2, GeF₄ may also break the bond between silicon and germanium in the silicon-germanium compound.

GeF₄ may also react with silicon fluoride (SiFₓ) according to the following Chemical Formula 3, where x may be a positive integer.

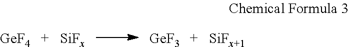

GeF₄ consumed in the reactions of Chemical Formulas 2 and 3 may be regenerated according to Chemical Formula 1 or the following Chemical Formula 4.

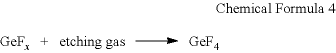

According to Chemical Formulas 1 to 4, GeF₄ may sequentially induce silicon-germanium etching reactions or bond dissociation reactions, resulting in improved etching efficiency of silicon-germanium.

Referring to FIG. 2, the concentration of GeFₓ may gradually decrease in a direction from the center of the substrate SUB toward the edge of the substrate SUB. As a result, the etching efficiency of silicon-germanium may be higher at the center of the substrate SUB and lower at the edge of the substrate SUB. For example, a difference in etching rate may occur between the center and the edge of the substrate SUB. This may be partially because reactants containing germanium and generating GeF₄ through an etching reaction, are absent in a region outside the edge of the substrate SUB. This may also be due to the shorter residence time of the fluid containing GeF₄ in a direction toward the edge of the substrate SUB.

Returning to FIG. 1, the auxiliary ring 24 may be provided at the edge of the stage 150. The auxiliary ring 24 may be spaced apart from the edge of the stage 150. For example, the auxiliary ring 24 may have a ring shape extending along the edge of the upper surface 152 of the stage 150. Accordingly, the auxiliary ring 24 may be adjacent to the edge of the substrate SUB loaded on the stage 150.

The auxiliary ring 24 may include the same material as the etch target. For example, the auxiliary ring 24 may include at least one of silicon, germanium, or carbon.

For example, the auxiliary ring 24 may include silicon-germanium. The etching gas may etch the auxiliary ring 24, and GeF₄ may be generated by the reaction of Chemical Formula 1 during the etching process.

Accordingly, the concentration of GeF₄ at the edge of the substrate SUB may increase due to the GeF₄ generated during the etching of the auxiliary ring 24.

In addition, the difference in etching rate between the center and the edge of the substrate SUB may be reduced.

In addition, a substrate processing apparatus 1 configured to uniformly etch the substrate SUB in a plan view may be provided.

In addition, a substrate processing apparatus 1 having improved reliability of the etching process may be provided.

The actuator 20 may drive the auxiliary ring 24. The actuator 20 may adjust a level of the auxiliary ring 24. The level may refer to a location in a vertical direction. The actuator 20 may also adjust a location of the auxiliary ring 24 in a horizontal direction. The actuator 20 may adjust an exposed area of the auxiliary ring 24. For example, the actuator 20 may adjust a distance between the substrate SUB loaded on the stage 150 and the auxiliary ring 24, and thus the exposed area of the upper surface 152 of the auxiliary ring 24 may be changed.

For example, the actuator 20 may include a fixing ring 23 and a drive ring 22 coupled to the auxiliary ring 24. The auxiliary ring 24 may be rotatably coupled to the fixing ring 23. For example, the auxiliary ring 24 may be coupled to the fixing ring 23 to be rotatable (e.g., rotated around the coupling).

The auxiliary ring 24 may be rotatably and movably coupled to the drive ring 22. For example, the auxiliary ring 24 may be coupled to the drive ring 22 to move in the horizontal direction and rotate in the plan view.

For example, in at least one embodiment, when the actuator 20 moves the auxiliary ring 24 in the horizontal direction, the fixing ring 23 may remain stationary and the drive ring 22 may rotate in the plan view.

The actuator 20 may include a drive motor 25 that rotates the drive ring 22 in the plan view. For example, the drive motor 25 may rotate the drive ring 22 within a certain angular range in the plan view. Accordingly, the drive ring 22 may reciprocally rotate within the certain angular range.

The actuator 20 may further include a driving shaft 26 and a driving gear 27. The drive motor 25 may transmit power to the drive ring 22 through the driving shaft 26 and the driving gear 27. For example, when the drive motor 25 operates, the driving shaft 26 and the driving gear 27 may rotate together to rotate the drive ring 22.

The actuator 20 may further include a lift 21 that adjusts a level of the auxiliary ring 24. The lift 21 may also adjust a level of the actuator 20. For example, the lift 21 may raise or lower the actuator 20 and the auxiliary ring 24.

Accordingly, the vertical level of the auxiliary ring 24 may be adjusted.

In addition, a distance between the substrate SUB loaded on the stage 150 and the auxiliary ring 24 may be adjusted.

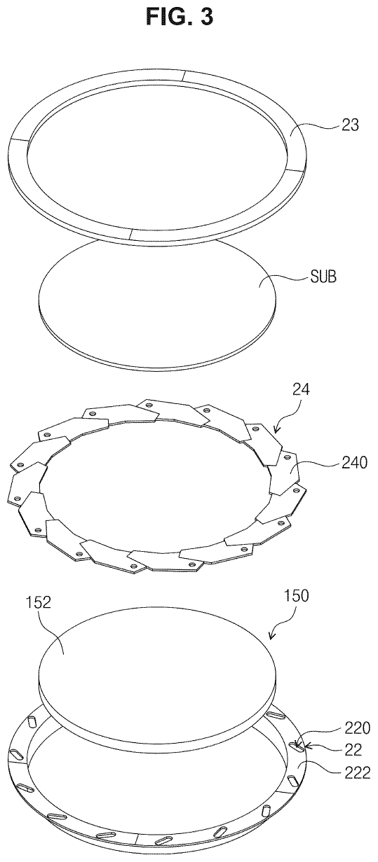

FIG. 3 is an exploded perspective view of a portion of the substrate processing apparatus 1 according to one or more embodiments.

Referring to FIG. 3, the auxiliary ring 24 may be provided between the fixing ring 23 and the drive ring 22. For example, the fixing ring 23 may be provided above the auxiliary ring 24, and the drive ring 22 may be provided below the auxiliary ring 24.

However, embodiments are not limited thereto. In one or more embodiments, the drive ring 22 may be provided above the auxiliary ring 24, and the fixing ring 23 may be provided below the auxiliary ring 24. For example, vertical locations of the drive ring 22 and the fixing ring 23 may vary.

The fixing ring 23 may extend along the edge of the stage 150. For example, the fixing ring 23 may have a ring shape extending in a circumferential direction along the edge of the upper surface 152 of the stage 150. The fixing ring 23 may cover the auxiliary ring 24. For example, the fixing ring 23 may cover at least a portion of an upper surface of the auxiliary ring 24.

The drive ring 22 may extend along the edge of the stage 150. For example, the drive ring 22 may have a ring shape extending in a circumferential direction along the edge of the upper surface 152 of the stage 150. The drive ring 22 may overlap the fixing ring 23 in the plan view. The auxiliary ring 24 may be seated on the drive ring 22.

The auxiliary ring 24 may be coupled to the fixing ring 23 and the drive ring 22. For example, the auxiliary ring 24 may be rotatably coupled to the fixing ring 23 and may be rotatably and movably coupled to the drive ring 22.

The auxiliary ring 24 may be radially spaced from the edge of the substrate SUB. In addition, the auxiliary ring 24 may be radially spaced from the edge of the stage 150.

The auxiliary ring 24 may include a plurality of auxiliary blades 240 arranged along the edge of the stage 150. The auxiliary blades 240 may be arranged along the circumferential direction of the stage 150. For example, the auxiliary blades 240 may be arranged in a circumferential direction along the edge of the upper surface 152 of the stage 150.

The auxiliary blades 240 may partially overlap each other in a plan view. The area of overlap may be using the actuator 20. In other words, the auxiliary blades 240 may be moved together by the actuator 20. For example, each of the auxiliary blades 240 may be coupled to the fixing ring 23 and the drive ring 22. For example, each of the auxiliary blades 240 may be rotatably coupled to the fixing ring 23 and may be rotatably and movably coupled to the drive ring 22.

Accordingly, an exposed area of each of the auxiliary blades 240 may also vary in the plan view.

In addition, a shortest distance between each of the auxiliary blades 240 and the substrate SUB loaded on the stage 150 may vary. For example, each of the auxiliary blades 240 may move closer to or farther from the stage 150 or the substrate SUB loaded on the stage 150.

Each of the auxiliary blades 240 may include the same material as the etch target. For example, each of the auxiliary blades 240 may include at least one of silicon, germanium, or carbon. For example, each of the auxiliary blades 240 may include silicon-germanium.

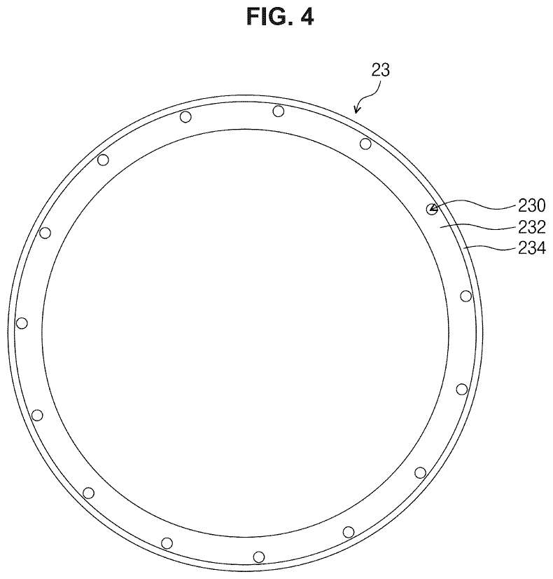

FIG. 4 is a plan view of the fixing ring 23 according to one or more embodiments.

Referring to FIG. 4, the fixing ring 23 may include a fixed plate 232, extending in a circumferential direction, and fixing holes 230. The fixed plate 232 may correspond to one surface of the fixing ring 23. For example, the fixed plate 232 may correspond to the upper surface of the fixing ring 23.

The fixing holes 230 may be defined within the fixed plate 232. The fixing holes 230 may be arranged along the circumference of the fixing ring 23. For example, the fixing holes 230 may be arranged in a circumferential direction and spaced apart from each other in the plan view.

The fixing holes 230 may be coupled to the auxiliary ring 24. For example, each of the fixing holes 230 may be rotatably coupled to each of the auxiliary blades 240. For example, each of the auxiliary blades 240 may rotate while being coupled to each of the fixing holes 230.

The fixing ring 23 may further include a fixed cover 234. The fixed cover 234 may correspond to a side surface of the fixing ring 23. The fixed cover 234 may vertically protrude from the fixed plate 232 and extend in a circumferential direction of the fixing ring 23.

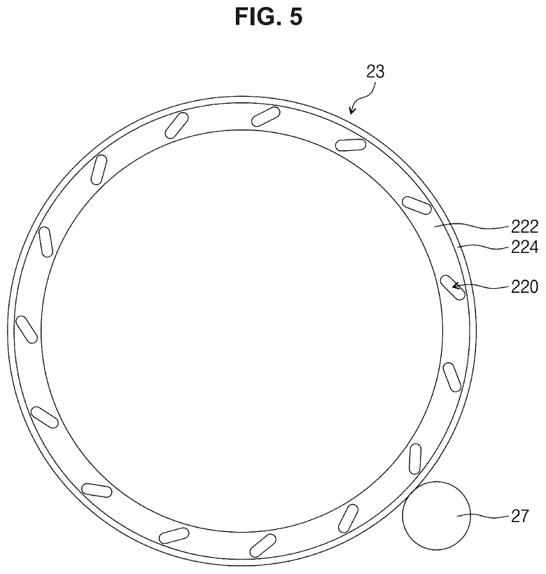

FIG. 5 is a plan view of the drive ring 22 according to one or more embodiments.

Referring to FIG. 5, the drive ring 22 may include a driving plate 222, extending in a circumferential direction, and driving holes 220. The driving plate 222 may correspond to one surface of the drive ring 22. For example, the driving plate 222 may correspond to a lower surface of the drive ring 22.

The driving holes 220 may be defined within the driving plate 222. The driving holes 220 may be arranged along the circumference of the drive ring 22. For example, the driving holes 220 may be arranged in a circumferential direction and spaced apart from each other in the plan view.

The driving holes 220 may extend to be elongated. For example, the driving holes 220 may extend to be elongated in a diagonal direction in the plan view. For example, the driving holes 220 may extend to move farther away from the center of the drive ring 22 in a clockwise direction.

The driving holes 220 may be coupled to the auxiliary ring 24. For example, each of the driving holes 220 may be rotatably and movably coupled to each of the auxiliary blades 240. For example, each of the auxiliary blades 240 may slidably rotate within each of the driving holes 220.

The drive ring 22 may further include a driving cover 224. The driving cover 224 may correspond to a side surface of the drive ring 22. The driving cover 224 may vertically protrude from the driving plate 222 and extend in a circumferential direction of the drive ring 22.

The drive ring 22 may engage with the driving gear 27. The driving gear 27 may be provided on one side of the drive ring 22 and engage with the edge of the drive ring 22. When the driving gear 27 rotates, the drive ring 22 may also rotate. For example, the driving gear 27 may be rotated by the drive motor 25, and the driving force of the drive motor 25 may be transmitted to the drive ring 22 through the driving gear 27.

Accordingly, the drive ring 22 may reciprocally rotate within a certain angular range in the plan view. For example, the drive ring 22 may rotate in a clockwise or counterclockwise direction within a certain angular range.

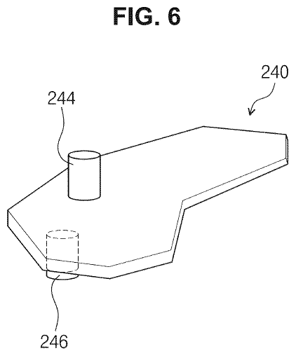

FIG. 6 is a perspective view of an auxiliary blade 240 according to one or more embodiments.

Referring to FIG. 6, the auxiliary blade 240 may include a fixing pin 244 on one surface and a driving pin 246 on the opposite surface. Another surface of the auxiliary blade 240 may oppose the one surface of the auxiliary blade 240.

The fixing pin 244 may protrude from the one surface of the auxiliary blade 240. The fixing pin 244 may be coupled to the fixing ring 23. For example, the fixing pin 244 may be rotatably coupled to the fixing hole 230 of the fixing ring 23. For example, the auxiliary blade 240 may rotate while being coupled to the fixing ring 23.

The driving pin 246 may protrude from the opposite surface of the auxiliary blade 240. The driving pin 246 may be spaced apart from the fixing pin 244 in the plan view. The driving pin 246 may be coupled to the drive ring 22. For example, the driving pin 246 may be rotatably and slidably coupled to the driving hole 220 of the drive ring 22. For example, the auxiliary blade 240 may rotate and slide while being coupled to the drive ring 22.

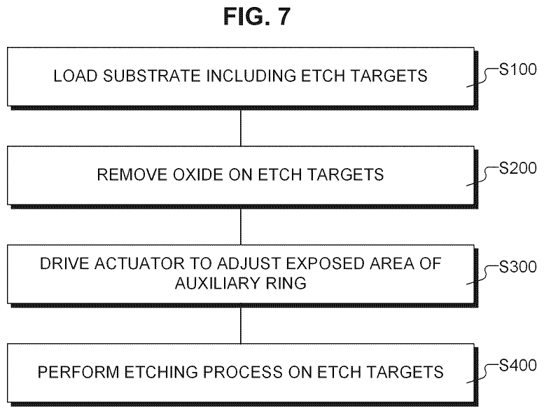

FIG. 7 is a flowchart illustrating a method of operating a substrate processing apparatus according to one or more embodiments.

Referring to FIG. 7, the method of operating the substrate processing apparatus (hereinafter referred to as an “operation method”) may include loading a substrate including etch targets (S100) and driving an actuator to adjust the exposed area of an auxiliary ring (S300).

The driving of the actuator (S300) may include moving each of the auxiliary blades toward the substrate. As a result, each of the auxiliary blades may move closer to the substrate SUB, and a shortest distance between the substrate and each of the auxiliary blades may decrease. In addition, the exposed area of each of the auxiliary blades may increase.

The driving of the actuator (S300) may also include moving each of the auxiliary blades away from the substrate. As a result, the shortest distance between the substrate and each of the auxiliary blades may increase. In addition, the exposed area of each of the auxiliary blades may decrease.

The driving of the actuator (S300) may also include raising or lowering the auxiliary ring. For example, the actuator may raise or lower each of the auxiliary blades. As a result, the level of the auxiliary blades may be adjusted.

The operation method may further include removing an oxide layer from the etch targets (S200). The removing of the oxide layer (S200) may be performed before driving the actuator S300.

The operation method may further include performing an etching process on the etch targets of the substrate (S400). The performing of the etching process (S400) may follow the removing of the oxide layer (S200). The driving of the actuator S300 may be performed during the etching process. In one or more embodiments, the driving of the actuator (S300) may be performed before the etching process.

The operation method may further include heating or cooling the substrate, not illustrated. For example, a temperature of the substrate may be controlled by the stage. As a result, the substrate may be heated or cooled to a temperature suitable for the etching process.

The operation method may further include adjusting a pressure in the processing space, not illustrated. For example, the pressure in the processing space may be controlled by an exhaust pump. For example, the substrate processing apparatus may adjust the concentration, amount, residence time, or discharge speed of the etching gas and etching products in the processing space.

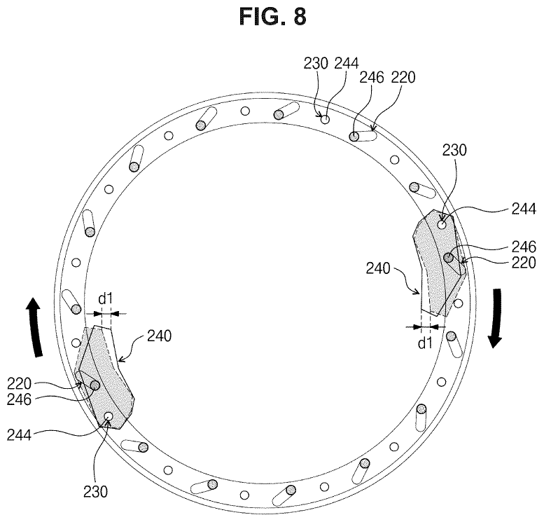

FIG. 8 is a plan view illustrating the operation of an auxiliary blade 240 according to one or more embodiments.

Referring to FIGS. 7 and 8, the drive ring 22 may rotate in one direction. For example, the drive ring 22 may rotate clockwise or counterclockwise in the plan view. FIG. 8 illustrates the operation of the auxiliary blade 240 as the drive ring 22 rotates clockwise in the plan view.

As the drive ring 22 rotates, the driving pin 246 of the auxiliary blade 240 may move within the driving hole 220 of the drive ring 22. The driving pin 246 of the auxiliary blade 240 may move toward one end of the driving hole 220. The driving hole 220 may guide the movement of the driving pin 246.

For example, as the drive ring 22 rotates in one direction, the auxiliary blade 240 may rotate and move. For example, when the drive ring 22 rotates clockwise, the driving hole 220 may transmit power to the driving pin 246 of the auxiliary blade 240. Subsequently, the driving pin 246 may slide toward one end of the driving hole 220, and the auxiliary blade 240 may move toward the center of the drive ring 22 by a first distance d1. One end of the driving hole 220 may be closer to the center of the drive ring 22 than another end of the driving hole 220.

Accordingly, the exposed area of the auxiliary blade 240 may increase in the plan view.

In addition, as the auxiliary blade 240 moves closer to the substrate SUB loaded on the stage 150, the shortest distance between the substrate SUB and the auxiliary blade 240 may decrease.

As the drive ring 22 rotates in the opposite direction, the auxiliary blade 240 may rotate and move. For example, when the drive ring 22 rotates counterclockwise, the driving hole 220 may transmit power to the driving pin 246 of the auxiliary blade 240. Then, the driving pin 246 may slide toward another end of the driving hole 220, and the auxiliary blade 240 may move away from the center of the drive ring 22.

Accordingly, the exposed area of the auxiliary blade 240 may decrease in the plan view.

In addition, as the auxiliary blade 240 moves away from the substrate SUB loaded on the stage 150, a shortest distance between the substrate SUB and the auxiliary blade 240 may increase.

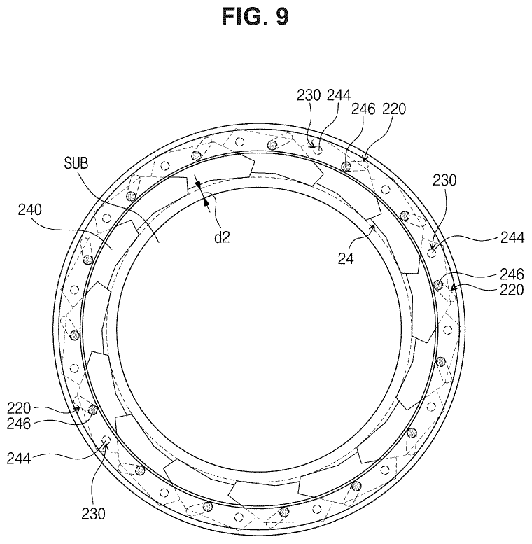

FIG. 9 is a plan view illustrating the operating state of the auxiliary blades 240 according to one or more embodiments.

Referring to FIGS. 7 and 9, each of the auxiliary blades 240 may be coupled to the drive ring 22. For example, the driving pin 246 of each of the auxiliary blades 240 may be coupled to the driving hole 220 of the drive ring 22.

When the driving pin 246 of each of the auxiliary blades 240 is positioned at one end of the driving hole 220, the auxiliary blades 240 may be maximally extended from the fixing ring 23. The exposed area of the auxiliary blades 240 may correspond to a maximum value. However, the auxiliary blades 240 may be configured such that the auxiliary blades 240, when fully extended from the fixing ring 23, do not overlap the substrate SUB in the plan view. For example, in some embodiments, the auxiliary blades 240 may not cover the substrate SUB. In other words, an internal diameter of the auxiliary ring 24 when the auxiliary blades 240 are fully extended may be greater than a diameter of the substrate SUB and/or of substrate loading area of the stage 150.

In addition, a shortest distance d2 between each of the auxiliary blades 240 and the substrate SUB loaded on the stage 150 may correspond to a minimum value.

As a result, the concentration of etching byproducts near the edge of the substrate SUB may increase. In addition, a difference between the concentration of etching byproducts at the edge of the substrate SUB and at the center of the substrate SUB may decrease.

Accordingly, a substrate processing apparatus configured to uniformly etch the substrate in the plan view may be provided.

In addition, a substrate processing apparatus 1 having improved reliability of the etching process may be provided.

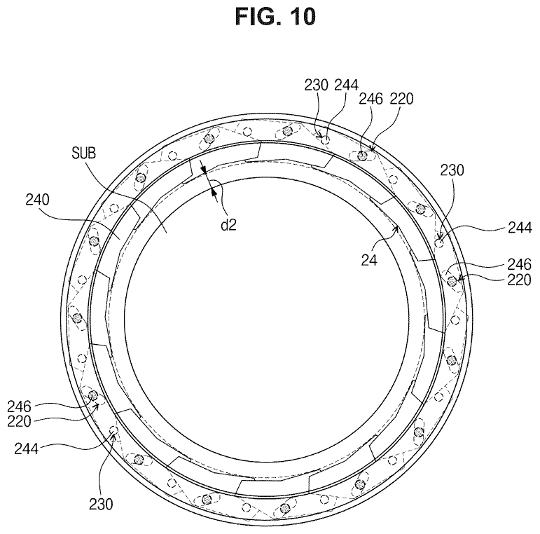

FIG. 10 is a plan view illustrating the operating state of the auxiliary blades 240 according to one or more embodiments.

Referring to FIGS. 7 and 10, each of the auxiliary blades 240 may be inserted into the fixing ring 23. For example, each of the auxiliary blades 240 may be inserted into a space disposed below the fixing ring 23. A portion of an upper surface of the auxiliary blade 240 may still be exposed.

For example, when the driving pin 246 of each of the auxiliary blades 240 moves from one end of the driving hole 220 toward another end thereof, the auxiliary blades 240 may be moved downwardly of the fixing ring 23. As a result, the exposed area of the auxiliary blades 240 may decrease from a maximum value. In addition, the shortest distance d2 between each of the auxiliary blades 240 and the substrate SUB loaded on the stage 150 may increase from a minimum value.

As a result, the substrate processing apparatus 1 may control the exposed area of the auxiliary blades 240 and the shortest distance to the substrate SUB to adjust the etching reaction speed.

In addition, the substrate processing apparatus 1 may control the exposed area of the auxiliary blades 240 and the shortest distance to the substrate SUB to adjust the concentration of etching byproducts at the edge of the substrate SUB.

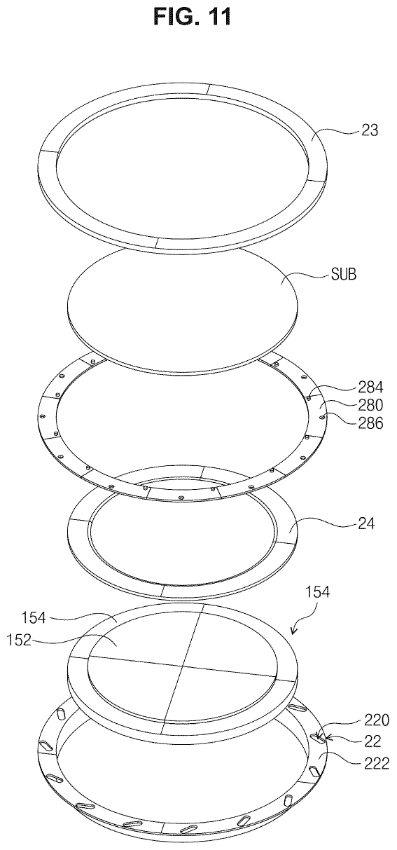

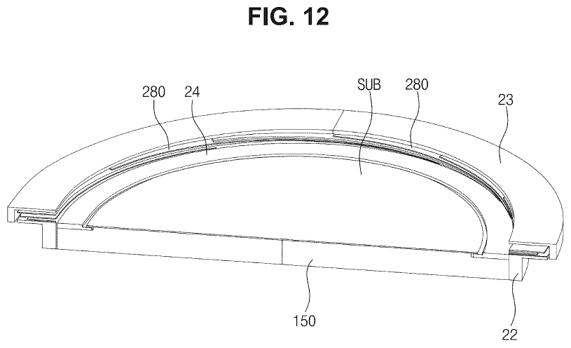

FIG. 11 is an exploded perspective view of a portion of the substrate processing apparatus according to one or more embodiments. FIG. 12 is a cross-sectional perspective view of a portion of the substrate processing apparatus according to one or more embodiments.

Most of the components and materials constituting the substrate processing apparatus to be described below are substantially the same or substantially similar to those of the substrate processing apparatus 1 described above with reference to FIGS. 1 and 3. Therefore, to avoid redundancy, the following description will focus primarily on the differences from the above-described substrate processing apparatus 1, and repeat descriptions thereof may be omitted.

Referring to FIGS. 11 and 12, in one or more embodiments, the auxiliary ring 24 may have a ring shape extending along the circumference of an upper surface 152 of the stage 150. The auxiliary ring 24 may be seated on the stage 150. For example, the auxiliary ring 24 may be seated on the edge of the stage 150.

The stage 150 may include a seating portion 154 surrounding the upper surface 152. The seating portion 154 may be recessed portion around the edge of the stage 150. A level of the seating portion 154 may be lower than that of the upper surface 152. The seating portion 154 may extend along the edge of the stage 150, and the upper surface 152 may be disposed at the center of the seating portion 154.

The substrate SUB may be loaded on the upper surface 152 of the stage 150, and the auxiliary ring 24 may be provided on the seating portion 154 of the stage 150. The substrate SUB and the auxiliary ring 24 may partially overlap in the plan view. For example, the outer circumference of the substrate SUB may overlap an inner edge of the auxiliary ring 24 in the plan view.

The substrate processing apparatus 1 may further include cover blades 280 coupled to the fixing ring 23 and the drive ring 22. The cover blades 280 may be provided at the edge of the stage 150. The cover blades 280 may be spaced apart from the edge of the stage 150. For example, the cover blades 280 may be adjacent to the edge of the substrate SUB loaded on the stage 150.

The actuator 20 may drive the cover blades 280. The actuator 20 may adjust a horizontal location of each of the cover blades 280. The actuator 20 may adjust an exposed area of each of the cover blades 280. For example, the actuator 20 may adjust a shortest distance between the substrate SUB loaded on the stage 150 and each of the auxiliary blades 240 to change the exposed area of the upper surface 152 of each of the cover blades 280.

The cover blades 280 may be provided between the auxiliary ring 24 and the drive ring 22. For example, the fixing ring 23 may be provided above the cover blades 280, and the drive ring 22 may be provided below the cover blades 280.

Each of the cover blades 280 may be coupled to the fixing ring 23 and the drive ring 22. For example, each of the cover blades 280 may be rotatably coupled to the fixing ring 23 and may be rotatably and movably coupled to the drive ring 22.

The cover blades 280 may be arranged along the edge of the stage 150. The cover blades 280 may be arranged in the circumferential direction of the stage 150. For example, the cover blades 280 may be arranged in a circumferential direction along the seating portion 154 of the stage 150.

The cover blades 280 may overlap each other in the plan view. The cover blades 280 may move together by the actuator 20.

Accordingly, the exposed area of each of the cover blades 280 may be changed in the plan view.

In addition, the shortest distance between each of the cover blades 280 and the substrate SUB loaded on the stage 150 may be changed. For example, each of the cover blades 280 may move closer to or farther from the stage 150 or the substrate SUB loaded on the stage 150.

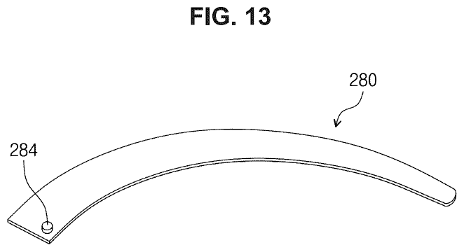

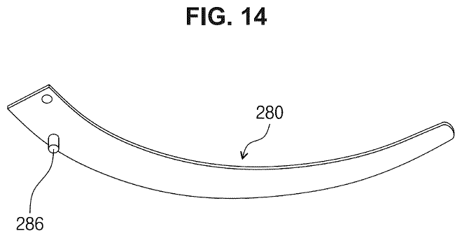

FIG. 13 is a perspective view of a cover blade 280 according to one or more embodiments. FIG. 14 is a perspective view of a cover blade 280 according to one or more embodiments.

Referring to FIGS. 13 and 14, the cover blade 280 may include a fixing pin 284 on one surface and a driving pin 286 on another surface. The another surface of the cover blade 280 may oppose the one surface of the cover blade 280.

The fixing pin 284 may protrude from the one surface of the cover blade 280. The fixing pin 284 may be coupled to the fixing ring 23. For example, the fixing pin 284 may be rotatably coupled to the fixing hole 230 of the fixing ring 23. For example, the cover blade 280 may rotate while being coupled to the fixing ring 23.

The driving pin 286 may protrude from the another surface of the cover blade 280. The driving pin 286 may be spaced apart from the fixing pin 284 in the plan view. The driving pin 286 may be coupled to the drive ring 22. For example, the driving pin 286 may be rotatably and slidably coupled to the driving hole 220 of the drive ring 22. For example, the cover blade 280 may rotate and slide while being coupled to the drive ring 22.

The cover blades 280 may extend along the edge of the auxiliary ring 24. For example, the cover blades 280 may extend curvilinearly.

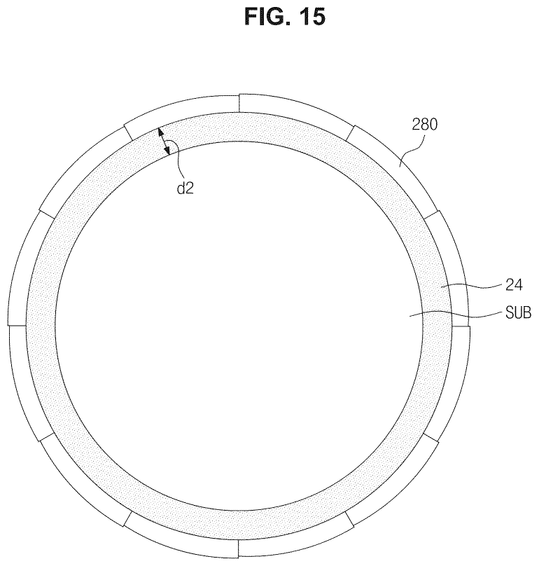

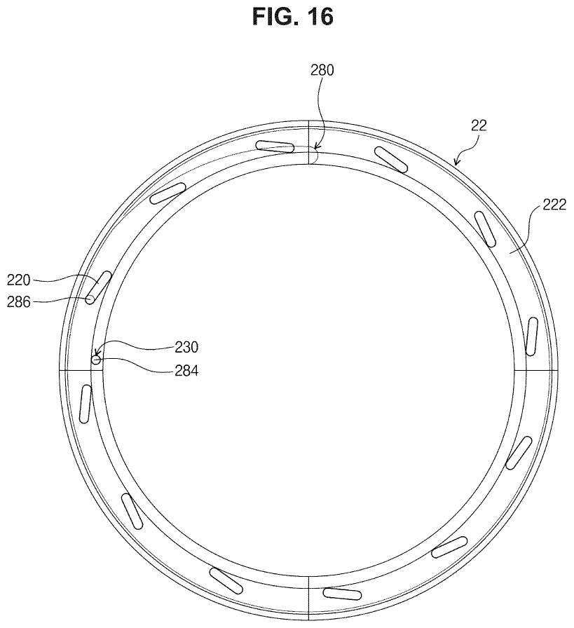

FIG. 15 is a plan view illustrating the operating state of the cover blades 280 according to one or more embodiments. FIG. 16 is a plan view illustrating the operating state of one of the cover blades 280 according to one or more embodiments.

Returning to FIG. 7, the driving of the actuator 20 may include moving each of the cover blades 280 toward the substrate SUB. As a result, each of the cover blades 280 may cover a portion of the auxiliary ring 24, and the exposed area of the auxiliary ring 24 may decrease.

The driving of the actuator 20 may include moving each of the cover blades 280 away from the substrate SUB. As a result, each of the cover blades 280 may expose the auxiliary ring 24, and the exposed area of the auxiliary ring 24 may increase.

Referring to FIGS. 7, 15, and 16, the driving holes 220 may be elongated. For example, the driving holes 220 may be elongated in a diagonal direction in the plan view. For example, the driving holes 220 may extend closer to the center of the drive ring 22 in a clockwise direction.

Each of the driving holes 220 may be rotatably and movably coupled to each of the cover blades 280. For example, each of the cover blades 280 may slide and rotate within each of the driving holes 220.

As the drive ring 22 rotates, the driving pin 286 of the cover blade 280 may move within the driving hole 220 of the drive ring 22. The driving pin 286 of the cover blade 280 may move toward one end of the driving hole 220. The driving hole 220 may guide the movement of the driving pin 286.

The driving hole 220 may include one end and another end. The one end may be closer to the center of the driving hole 220 than the another end.

When the driving pin 286 of each of the cover blades 280 is disposed at the another end of the driving hole 220, the cover blades 280 may be inserted into a space disposed below the fixing ring 23. The cover blades 280 may be fully inserted into a space disposed below the fixing ring 23, and the auxiliary ring 24 may be fully exposed in the plan view.

Accordingly, the exposed area of the auxiliary ring 24 may correspond to a maximum value.

In addition, the exposed area of the cover blades 280 may correspond to a minimum value.

In addition, a shortest distance between each of the cover blades 280 and the substrate SUB loaded on the stage 150 may correspond to a maximum value.

As a result, the concentration of etching byproducts near the edge of the substrate SUB may increase. In addition, a difference between the concentration of etching byproducts at the edge of the substrate SUB and the concentration of etching byproducts at the center of the substrate SUB may decrease.

Accordingly, a substrate processing apparatus configured to uniformly etch the substrate SUB in the plan view may be provided.

In addition, a substrate processing apparatus having improved reliability of the etching process may be provided.

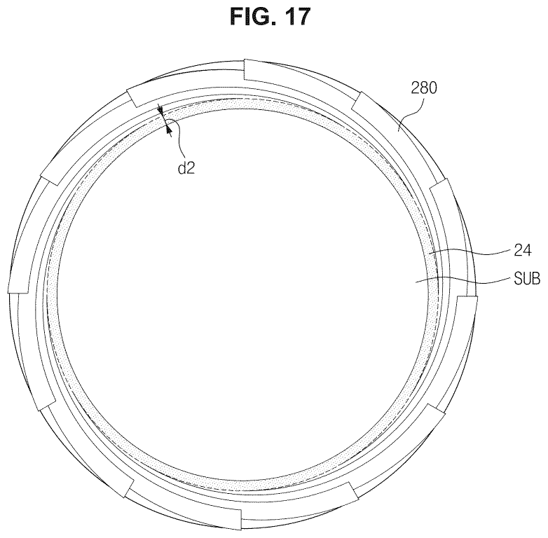

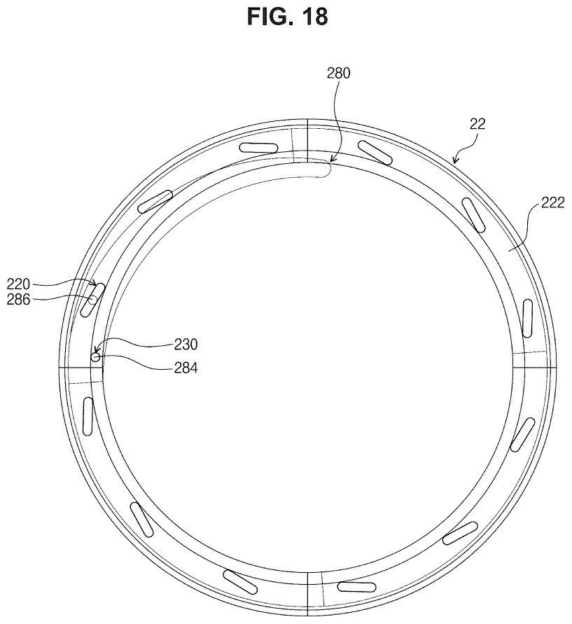

FIG. 17 is a plan view illustrating the operating state of the cover blades 280 according to one or more embodiments. FIG. 18 is a plan view illustrating the operating state of one of the cover blades 280 according to one or more embodiments.

Referring to FIGS. 7, 17, and 18, the drive ring 22 may reciprocally rotate within a certain angular range in the plan view. For example, the drive ring 22 may rotate clockwise or counterclockwise within a certain angular range.

As the drive ring 22 rotates in one direction, the driving pin 286 of the cover blade 280 may move within the driving hole 220 of the drive ring 22. The driving pin 286 of the cover blade 280 may move from another end of the driving hole 220 toward one end thereof. The driving hole 220 may guide the movement of the driving pin 286.

For example, as the drive ring 22 rotates in one direction, the cover blade 280 may be extended from a space disposed below the fixing ring 23. For example, when the drive ring 22 rotates counterclockwise, the driving hole 220 may transmit power to the driving pin 286 of the cover blade 280. Then, the driving pin 286 may slide toward one end of the driving hole 220, and the cover blade 280 may be extended toward the center of the drive ring 22.

The extended cover blade 280 may cover the auxiliary ring 24. For example, the cover blade 280 may overlap the auxiliary ring 24 in the plan view. However, the cover blade 280 may not overlap the substrate SUB in the plan view.

Accordingly, in the plan view, the exposed area of the cover blade 280 may increase from a minimum value, and the exposed area of the auxiliary ring 24 may decrease from a maximum value.

In addition, the cover blade 280 is extended from under the fixing ring 23 toward the center of the fixing ring 23, so that the shortest distance between the substrate SUB and the cover blade 280 may decrease.

As a result, the substrate processing apparatus may control the exposed area of the auxiliary ring 24 to adjust the etching reaction speed.

In addition, the substrate processing apparatus may control the exposed area of the auxiliary ring 24 to adjust the concentration of etching byproducts at the edge of the substrate SUB.

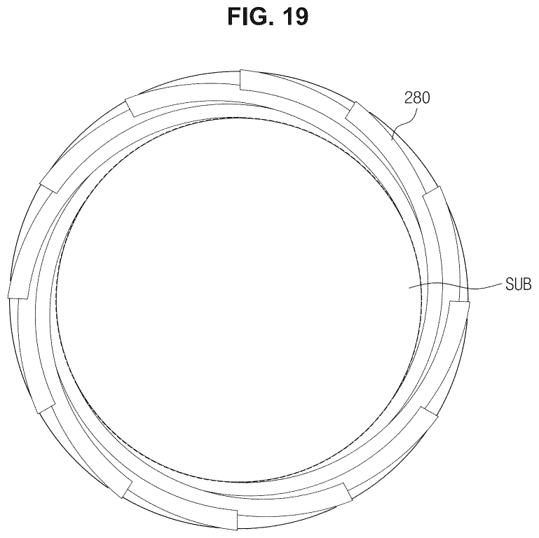

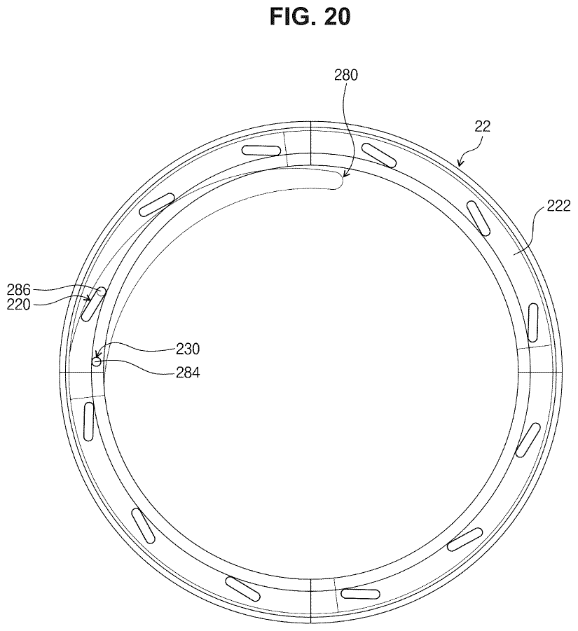

FIG. 19 is a plan view illustrating the operating state of the cover blades 280 according to one or more embodiments. FIG. 20 is a plan view illustrating the operating state of one of the cover blades 280 according to one or more embodiments.

Referring to FIGS. 7, 19, and 20, when the driving pin 286 of each of the cover blades 280 is disposed at one end of the driving hole 220, the cover blades 280 may be fully extended from the fixing ring 23. In the plan view, the exposed area of the cover blades 280 may correspond to a maximum value, and the exposed area of the auxiliary ring 24 may correspond to a minimum value. However, the cover blades 280 fully extended from the fixing ring 23 may not overlap the substrate SUB in the plan view. For example, the cover blades 280 may not cover the substrate SUB.

Accordingly, in the plan view, the exposed area of the cover blade 280 may correspond to a maximum value, and the exposed area of the auxiliary ring 24 may correspond to a minimum value.

In addition, the shortest distance between the substrate SUB and the cover blade 280 may correspond to a minimum value.

As a result, the substrate processing apparatus may control the exposed area of the auxiliary ring 24 to adjust the etching reaction speed.

In addition, the substrate processing apparatus may control the exposed area of the auxiliary ring 24 to adjust the concentration of etching byproducts at the edge of the substrate SUB.

As set forth above, according to some embodiments, a substrate processing apparatus having enhanced reliability of an etching process may be provided.

In addition, a substrate processing apparatus configured to etch a substrate uniformly in the plan view may be provided.

In addition, a substrate processing apparatus configured to control an etching reaction rate in an etching process may be provided.

In addition, a substrate processing apparatus configured to control the amount of products generated by an etching reaction in an etching process may be provided.

As set forth above, according to some embodiments, a method of operating a substrate processing apparatus including a chamber defining a processing space, a stage in the processing space, and an auxiliary ring extending along an edge of an upper surface of the stage, the method may include loading a substrate onto the upper stage of the stage; adjusting an exposed area of the auxiliary ring in a plan view; supplying a process fluid onto the substrate and onto the exposed area of the auxiliary ring. The etching target may have the same material as the auxiliary ring.

In addition, the supplying the process fluid onto the substrate and onto the exposed area of the auxiliary ring may include generating GeF₄ from the exposed area of the auxiliary ring.

In addition, the method may include removing an oxide from the etching target before the supplying the process fluid.

As set forth above, according to some embodiments, a method of manufacturing a semiconductor device, the method including, loading a substrate onto an upper surface of a stage in the processing space; adjusting an exposed area of an auxiliary ring surrounding the substrate; etching an etching target on the substrate and the exposed area of the auxiliary ring by supplying a processing fluid into the processing stage.

In addition, the supplying the process fluid may include generating GeF₄ from the exposed area of the auxiliary ring.

In addition, the supplying the process fluid may include generating GeF₄ from the exposed area of the auxiliary ring.

While various embodiments have been shown and described above, it will be apparent to those skilled in the art that modifications and variations could be made without departing from the scope of the present inventive concept as defined by the appended claims.

What is claimed is:

1. A substrate processing apparatus comprising:
a chamber defining a processing space;
a stage in the processing space and having an upper surface on which a substrate is loaded;
an auxiliary ring extending along an edge of the upper surface of the stage; and
an actuator configured to adjust a size of an exposed area of the auxiliary ring in a plan view,
wherein the substrate comprises an etch target, and
the auxiliary ring comprises a same material as the etch target of the substrate.

2. The substrate processing apparatus of claim 1, wherein:
the auxiliary ring comprises a plurality of auxiliary blades arranged along the edge of the upper surface of the stage; and
the plurality of auxiliary blades comprise the same material as the etch target of the substrate.

3. The substrate processing apparatus of claim 2, wherein:
the actuator is configured to move the plurality of auxiliary blades toward the stage and away from the stage.

4. The substrate processing apparatus of claim 3, wherein the actuator comprises:
a fixing ring extending along the edge of the stage;
a drive ring overlapping the fixing ring in the plan view; and
a drive motor configured to rotate the drive ring within an angular range; and
wherein the plurality of auxiliary blades are coupled to the fixing ring and the drive ring.

5. The substrate processing apparatus of claim 4, wherein each of the plurality of auxiliary blades comprises:
a fixing pin on a first surface of each of the plurality of auxiliary blades; and
a driving pin on a second surface of each of the plurality of auxiliary blades, the second surface opposing the first surface,
wherein the fixing ring comprises fixing holes into which the fixing pins of the plurality of auxiliary blades are fitted,
the drive ring comprises elongated driving holes in which the driving pins of the plurality of auxiliary blades are engaged, and
each of the driving pins is slidable within each of the elongated driving holes.

6. The substrate processing apparatus of claim 4, wherein:
an exposed area of the plurality of auxiliary blades increases when the drive ring rotates in one direction in the plan view; and
the exposed area of the plurality of auxiliary blades decreases when the drive ring rotates in a direction opposite to the one direction in the plan view.

7. The substrate processing apparatus of claim 4, wherein:
a shortest distance between each of the plurality of auxiliary blades and the upper surface of the stage decreases when the drive ring rotates in one direction in the plan view; and
the shortest distance between each of the plurality of auxiliary blades and the upper surface of the stage increases when the drive ring rotates in a direction opposite to the one direction in the plan view.

8. The substrate processing apparatus of claim 1, wherein the actuator comprises:
a fixing ring extending along the edge of the stage;
cover blades configured to extend from the fixing ring to cover the auxiliary ring and to be inserted into the fixing ring to expose the auxiliary ring; and
a drive ring configured to drive the cover blades to extend from the fixing ring or to be inserted into the fixing ring.

9. The substrate processing apparatus of claim 8, wherein each of the cover blades comprises:
a fixing pin on a first surface of each of the cover blades; and
a driving pin on a second surface of each of the cover blades, the second surface opposing the second surface,
wherein the fixing ring comprises fixing holes into which the fixing pins of the cover blades are fitted,
the drive ring comprises elongated driving holes in which the driving pins of the cover blades are engaged, and
each of the driving pins is slidable within each of the elongated driving holes.

10. The substrate processing apparatus of claim 1, wherein the same material comprises at least one of silicon, germanium, or carbon.

11. A substrate processing apparatus comprising:
a chamber defining a processing space;
a stage in the processing space, the stage configured to support a substrate;
a plurality of auxiliary blades arranged along an edge of the stage; and
an actuator coupled to the plurality of auxiliary blades,
wherein the substrate comprises an etch target,
each of the plurality of auxiliary blades comprises a same material as the etch target of the substrate, and
the actuator is configured to adjust a shortest distance between each of the plurality of auxiliary blades and the stage.

12. The substrate processing apparatus of claim 11, wherein:
the plurality of auxiliary blades are arranged to overlap each other in a plan view.

13. The substrate processing apparatus of claim 11, wherein:
the plurality of auxiliary blades is configured such that an internal diameter defined by the plurality of auxiliary blades is greater than a diameter of the substrate.

14. The substrate processing apparatus of claim 11, wherein:
the actuator further comprises a lift configured to move the plurality of auxiliary blades in a vertical direction.

15. The substrate processing apparatus of claim 11, wherein:
the same material comprises at least one of silicon, germanium, or carbon.

16. A substrate processing apparatus comprising:
a chamber defining a processing space;
a stage in the processing space, the stage comprising an upper surface on which a substrate is loaded and a seating portion recessed along an edge of the stage;
an auxiliary ring on the seating portion of the stage;
a plurality of cover blades arranged along the edge of the stage; and
an actuator configured to drive the plurality of cover blades to adjust a size of an exposed area of the auxiliary ring in a plan view,
wherein the plurality of cover blades are configured to extend from the actuator to cover the auxiliary ring and to be inserted into the actuator to expose the auxiliary ring;
the substrate comprises an etch target, and
the auxiliary ring comprises a same material the etch target of the substrate.

17. The substrate processing apparatus of claim 16, wherein:
the plurality of cover blades are arranged to overlap each other in a plan view.

18. The substrate processing apparatus of claim 16, wherein:
the plurality of cover blades are configured such that, when extended from the actuator, an internal diameter defined by the plurality of cover blades is greater than a diameter of the substrate.

19. The substrate processing apparatus of claim 16, wherein:
the plurality of cover blades extend curvilinearly along an edge of the auxiliary ring.

20. The substrate processing apparatus of claim 16, wherein:
the same material comprises at least one of silicon, germanium, or carbon.
